(19) United States
(12) Patent Application Publication
(10) Pub. No.: US 2026/0360673 A1
(43) Pub. Date: Nov. 12, 2026

(54) PROCESS KIT FOR SUBSTRATE PROCESS CHAMBERS

(71) Applicant: United Semiconductor (Xiamen) Co., Ltd., Xiamen (CN)

(72) Inventors: Haipeng Zhu, Shamen City (CN); Weiqiang Shi, Shamen City (CN); Jinggang Li, Singapore (SG); Ching-Shu Lo, Singapore (SG); Wen Yi Tan, Xiamen (CN)

(73) Assignee: United Semiconductor (Xiamen) Co., Ltd., Xiamen (CN)

(21) Appl. No.: 19/227,443

(22) Filed: Jun. 3, 2025

(30) Foreign Application Priority Data
May 8, 2025 (CN) 202510586562.7

(51) Int. Cl. H01J 37/32; H10P 72/72

(52) U.S. Cl. CPC H01J 37/32642; H01J 37/32522; H10P 72/722; H01J 37/32715; H01J 2237/002; H01J 2237/2007; H01J 2237/332

(57) ABSTRACT

A process kit for a substrate processing chamber, including: a cover ring having an annular body and a lip extending radially inward from the annular body, the bottom surface of the annular body having an inner ring and an outer ring extending downwardly to define an annular groove, wherein a plurality of recesses are uniformly and circumferentially distributed along the bottom surface of the annular groove, and a shield ring having a downwardly extending lower edge and an upper edge extending upward from the lower edge, the upper edge being configured to engage with the annular groove of the cover ring.

### BACKGROUND OF THE INVENTION

### 1. Field of the Invention

The present invention pertains to the field of semiconductor technology, and more specifically, to a process kit designed for use in substrate process chambers. It is particularly well-suited for applications involving high-performance, low-power, and low-leakage logic devices utilizing polysilicon gate/high-k metal gate (HKMG) architectures. Additionally, it is applicable to a wide range of related products and manufacturing processes, including mixed-signal devices, embedded memory, BCD (Bipolar-CMOS-DMOS) technologies, and high-voltage devices.

### 2. Description of the Prior Art

The fabrication of semiconductor devices involves a wide variety of processes and treatments applied to both the surface and bulk of the substrate (e.g., a wafer). These processes typically encompass chemical reactions such as diffusion, oxidation, and deposition, and may number in the hundreds throughout a full manufacturing flow. In deposition applications, materials originating from various sources - such as targets or process gases - can be deposited onto the exposed internal surfaces of the process chamber, including the chamber walls, substrate support, electrostatic chuck (ESC), and other hardware components, through suitable and compatible methods. One commonly used technique for such deposition is Physical Vapor Deposition (PVD). To protect the ESC from direct exposure to deposited materials during the deposition process, a process kit is typically employed. This kit may include components such as a cover ring, shield ring, and/or deposition ring. The deposition ring is generally mounted on a peripheral flange extending from the ESC, while the cover ring is placed over the shield ring and aligned with the deposition ring to prevent material buildup on the outer edge of the substrate and ESC.

Although the process kit serves a critical function in shielding the ESC during deposition, process-induced defects can still occur on the cover ring and deposition ring due to various process factors. For instance, the cover ring in the process kit may experience significant temperature increases during deposition, which can lead to thermal radiation affecting the outer edge of the substrate it covers. This, in turn, may result in process defects such as the formation of aluminum whiskers, which may degrade process stability and product yield. Conventional approaches attempt to address this issue by introducing cooling gases to reduce the cover ring's temperature. However, existing cover ring designs are often inadequate to meet the increasing thermal management demands of advanced process kits. Therefore, for those of skilled in the art, there is a need for improved cover ring designs to overcome the aforementioned limitations of conventional approaches.

### SUMMARY OF THE INVENTION

In light of the aforementioned limitations in the prior art, the present invention introduces a novel cover ring designed for use in a substrate process chamber. A key feature of this cover ring is the incorporation of multiple recesses within its annular groove. These recesses are strategically designed to increase the surface area of the cover ring in contact with the cooling gas flow, thereby significantly improving the heat dissipation performance of the cover ring. As a result, the deposition process on the substrate becomes more uniform and consistent.

One aspect of the present invention is to provide a process kit for a substrate process chamber, including: a cover ring having an annular body and a lip radially extending inward from the annular body, wherein a bottom surface of the annular body comprises an inner ring and an outer ring extending downward to define an annular groove, wherein a bottom surface of the annular groove comprises a plurality of recesses circumferentially and uniformly distributed along the bottom surface of the annular groove; and a shield ring having a lower edge portion extending inward and an end portion extending upward from the lower edge portion, the end portion being configured to engage with the annular groove of the cover ring.

Another aspect of the present invention is to provide a substrate process chamber, including: a substrate support configured to hold a substrate, the substrate support being disposed within an inner processing space of the substrate process chamber and having a deposition ring disposed thereon; and a process kit disposed at a peripheral edge of the substrate support, the process kit comprising: a cover ring having an annular body and a lip radially extending inward from the annular body, wherein a bottom surface of the annular body comprises an inner ring and an outer ring extending downward to define an annular groove, and a bottom surface of the annular groove comprises a plurality of recesses circumferentially and uniformly distributed along the bottom surface of the annular groove; and a shield ring having a lower edge portion extending inward and an end portion extending upward from the lower edge portion, the end portion being configured to engage with the annular groove of the cover ring.

Specifically, the present invention is well-suited for applications involving high-performance, low-power, and low-leakage logic devices utilizing polysilicon gate/ high-k metal gate (HKMG) architectures. Additionally, it is applicable to a wide range of related products and manufacturing processes, including mixed-signal devices, embedded memory, BCD (Bipolar-CMOS-DMOS) technologies, and high-voltage devices.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view of an integrated multi-chamber process tool.

FIG. 2 is a schematic cross-sectional view of a PVD process chamber in accordance with an embodiment of the present invention.

FIG. 3 is a front plan view of the cover ring.

FIG. 4 is a rear plan view of the cover ring.

FIG. 5 is a partial schematic cross-sectional view of the cover ring.

FIG. 6 is a schematic cross-sectional view showing the installation of the process kit within a substrate process chamber; and

FIG. 7 is a schematic cross-sectional view comparing the heat dissipation performance of a conventional cover ring with that of the cover ring of the present invention.

It should be noted that all the figures are diagrammatic and illustrative. Relative dimensions and proportions of parts in the drawings have been shown exaggerated or reduced in size for the sake of clarity and convenience. The same reference signs and numerals are generally used to refer to corresponding or similar features in various modified or alternative embodiments.

### DETAILED DESCRIPTION

The present invention generally relates to a process kit designed for use in semiconductor process chambers. This process kit includes a cover ring that is uniquely characterized by an array of recesses arranged in an annular pattern. This innovative design significantly enhances airflow circulation and heat transfer around the periphery of the process chamber, leading to a more uniform and consistent processing environment. While the following embodiments are described and illustrated with reference to a Physical Vapor Deposition (PVD) process chamber, the scope of the invention is not limited to this application. Indeed, the invention is also applicable to other types of semiconductor process chambers, such as Chemical Vapor Deposition (CVD) chambers, Atomic Layer Deposition (ALD) chambers, and similar technologies.

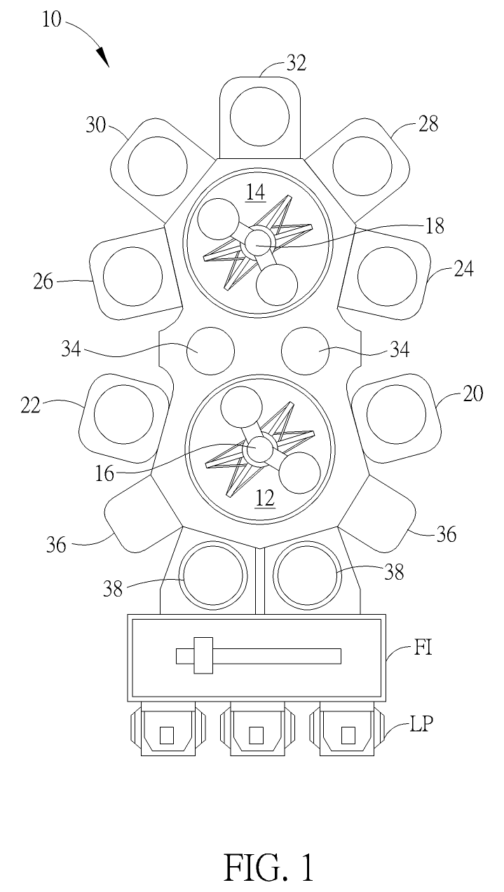

First, FIG. 1 illustrates a top view of an integrated multi-chamber process tool 10. The substrate referenced herein may be a semiconductor wafer, and the process tool 10 is suitable and configured to perform at least one deposition and annealing process on the substrate, as described throughout this disclosure. These deposition and annealing processes can be carried out in a multi-chamber substrate process tool or in a cluster tool that includes one or more Atomic Layer Deposition (ALD) chamber, at least one Chemical Vapor Deposition (CVD) chamber, at least one Physical Vapor Deposition (PVD) chamber, or at least one annealing chamber. An example of the process tool or system for implementing the present invention is the ENDURA® process tool, commercially available from Applied Materials, Inc., based in Santa Clara, California, USA. During operation, the substrate or wafer to be processed—initially located outside the tool—is housed in a wafer carrier such as a Front Opening Unified Pod (FOUP) or a Standard Mechanical Interface (SMIF) pod. These carriers can be loaded into a factory interface (FI) via a wafer loading/unloading port (LP). The factory interface FI functions as the communication bridge between the external factory environment and the process tool 10. It enables actions such as tool and wafer data collection and acquisition, while also allowing for pre-processing operations like wafer alignment and orientation within the factory interface FI prior to transfer into the tool.

Referring again to FIG. 1, in the illustrated embodiment, the process tool 10 includes two transfer chambers 12 and 14 - designated as first transfer chamber 12 and second transfer chamber 14 — each equipped with a respective transfer robot 16 and 18. A plurality of process chambers 20, 22, 24, 26, 28, 30, and 32 are positioned adjacent to and accessible from the two transfer chambers 12 and 14. A pass-through chamber 34 is interposed between the first and second transfer chambers 12 and 14 to physically and functionally separate them. This pass-through chamber 34 may include a cooling chamber or a preheating chamber, depending on the process requirements. When the first and second transfer chambers 12 and 14 operate under different pressure regimes, the pass-through chamber 34 facilitates controlled substrate transfer by enabling evacuation or venting during wafer handoff. For example, the operating pressure in the first transfer chamber 12 may be approximately 100 mTorr to 5 Torr (e.g., about 400 mTorr), while the operating pressure in the second transfer chamber 14 may operate at high vacuum levels, ranging from approximately 1×10⁻⁵ Torr to 1×10⁻⁸ Torr (e.g., about 1×10⁻⁷ Torr). The pass-through chamber 34 can be evacuated or vented to equalize the pressure between the two chambers and/or to reach the desired operating pressure for each chamber during the transfer. All of the aforementioned operations may be automated and executed through a program-controlled microprocessor, enabling precise, efficient, and repeatable process flows.

Referring again to FIG. 1, in the illustrated embodiment, the first transfer chamber 12 is operably connected to two degas chambers 36, two load lock chambers 38, and two process chambers 20 and 22. The process chambers 20 and 22 may be configured as either CVD or PVD chambers, used for depositing adhesive or antireflective layers, such as those composed of titanium/titanium nitride (Ti/TiN) materials. The process chambers 20 and 22 may also be implemented, for example, as PreClean II pre-cleaning process chambers, commercially available from Applied Materials, Inc. headquartered in Santa Clara, California, USA - though other configurations may be used as well. Substrates or wafers prepared in the factory interface FI (not shown) are loaded into the process tool 10 via the load lock chamber 38. Once inside, the substrates sequentially undergo degassing in the degas chambers 36, followed by surface preparation or thin film deposition in process chambers 20 and 22, where Ti/TiN films may be applied. The transfer robot 16 within the first transfer chamber 12 transfers the substrates or wafers between the degas chambers 36 and the process chambers 20 and 22, ensuring efficient and accurate handling throughout the workflow.

Continuing with FIG. 1, the second transfer chamber 14 is operably coupled to a cluster of chambers that include process chambers 24, 26, 28, 30, and 32. In one embodiment, these process chambers 24, 26, 28, 30, and 32 are implemented as PVD chambers, which employ a magnetron sputtering techniques to deposit aluminum (Al) layers on a substrate or wafer. Additionally, some of these process chambers 24, 26, 28, 30, and 32 may also be used to deposit adhesive or antireflective layers composed of titanium/titanium nitride (Ti/TiN) materials. Substrates processed in the PVD chambers are transferred from the first transfer chamber 12 to the second transfer chamber 14 via the pass-through chamber 34. Subsequently, the transfer robot 18 within the second transfer chamber 14 can transfer the substrate between one or more of the process chambers 24, 26, 28, 30, and 32 to execute the necessary deposition steps and treatments.

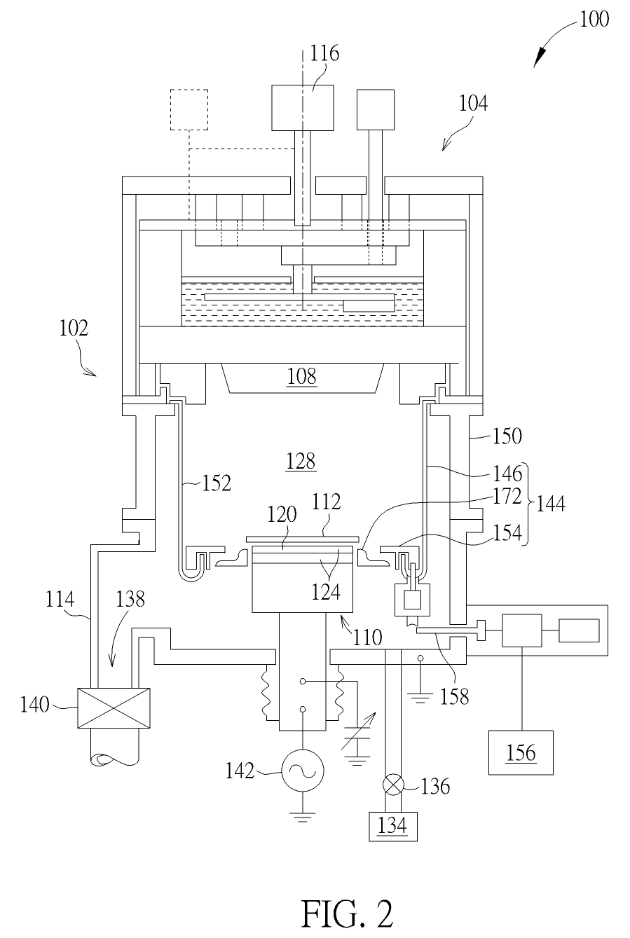

Next, referring to FIG. 2, a simplified schematic cross-sectional view of a Physical Vapor Deposition (PVD) process chamber is illustrated in accordance with an embodiment of the present invention. This type of PVD process chamber may correspond to any of the aforementioned process chambers 24, 26, 28, 30, or 32, and is configured to perform sputter deposition of desired material layers onto a substrate. One example of a suitable PVD process chamber that can be adapted based on the teachings of the present disclosure is the SIP ENCORE® PVD chamber, commercially available from Applied Materials, Inc. However, the invention is not limited to this model and can also be implemented in other chambers offered by Applied Materials or other manufacturers.

In certain embodiments, the substrate process system 100 includes a process chamber 102, which is enclosed by a chamber cover 104 mounted above it. The chamber cover 104 may include a target assembly as well as a grounding assembly. Within the process chamber 102, a substrate support 110 is provided to receive and hold a substrate 112 during processing. The substrate support 110 is typically installed in a lower grounded wall 114, which forms part of the chamber enclosure of the process chamber 102. This lower grounded wall 114 may be electrically connected to the grounding assembly of the chamber cover 104, thereby providing an RF (radio frequency) path to an RF power source 116 positioned above the chamber cover 104. Alternatively, in some embodiments, the RF return path may be established through a shield ring included in the process kit, allowing the circuit to complete from the substrate support 110 back to the grounding assembly of the chamber cover 104.

The RF power source 116 is configured to supply RF power to the target assembly. In certain embodiments, a first bias power supply 142 may provide pulsed RF energy to the target assembly. For example, the RF energy supplied by RF power source 116 can be used for high-pulse magnetron sputtering. This technique enhances ionization of the sputtered material, resulting in improved film quality and deposition control. The target assembly includes a target 108, which serves as the material source for deposition. Various types of materials can be used, such as metals, metal oxides, metal alloys, and the like, which are deposited onto the substrate 112 during processing. The substrate support 110 features a material-receiving surface that faces the target 108, and the substrate (e.g., a semiconductor wafer) 112 is positioned on a plane aligned with the target for optimal exposure. The substrate support 110 may include a dielectric component 120 along with one or more conductive elements 124. These conductive elements may form part of an electrostatic chuck (E-chuck), RF electrode, or similar system, and serve to either hold the substrate in place via electrostatic force or deliver RF energy as part of the process.

The substrate support 110 is designed to support the substrate 112 within the space 128 of the process chamber 102, while also isolating it from other internal spaces or areas during the deposition process. In this embodiment, the substrate support 110 may move vertically, allowing the substrate 112 to be transferred to the substrate support 110 via a feed port located at the bottom of the process chamber 102, and then elevated to the deposition or processing position. A gas source 134 can supply one or more process gases to the process chamber 102 through a flow control component 136. To maintain the appropriate processing conditions, an exhaust port 138 is provided and connected to a pump, which expels gases from the interior of the process chamber 102 through a valve 140, maintaining the required pressure inside the process chamber 102 throughout the process.

The process chamber 102 is further equipped with a process kit 144. The process kit may consist of multiple components installed within the chamber, particularly in the area where the substrate and mechanism are located. In one exemplary embodiment, the process kit 144 may include a shield ring 146, which is grounded and surrounds the space 128 of the process chamber 102 to protect other chamber components from damage or contamination during the process, such as preventing sputter deposition from affecting the process chamber 102. In some implementations, the shield ring 146 may be mechanically and electrically coupled to an upper grounded wall 150 of the process chamber 102. Together with the lower grounded wall 114, the upper grounded wall 150 forms part of the RF loop between the chamber cover 104 and the lower grounded wall 114. In one embodiment, the shield ring 146 may include one or more sidewalls 152, which are designed to encircle the space 128 and extend downward below the top surface of the substrate support 110, and then curve back toward the surface of the substrate support 110, forming a U-shaped portion at the bottom of the shield ring 146. This U-shaped portion is specifically engineered to facilitate structural integration with other process kit components, such as a cover ring, while also enhancing particle containment and shielding performance during deposition.

In the present invention, the process kit 144 further includes a cover ring 154, which may be fabricated from a process-compatible conductive material, such as stainless steel. The cover ring 154 can also be made from a non-conductive material, such as ceramic. When the substrate support 110 is positioned in a lower loading state, the cover ring 154 can be mounted on the U-shaped portion of the shield ring 146. In contrast, when the substrate support 110 is elevated to a higher processing position (as depicted in FIG. 1), the cover ring 154 is positioned around the substrate support 110 and substrate 112 to protect the periphery of the substrate 112 from sputter deposition. In certain embodiments, as illustrated in FIG. 1, the process kit 144 may also include a deposition ring 172, which is installed around the perimeter of the substrate support 110 to shield the edge of the substrate support 110 from material deposition. The deposition ring 172 can also be configured to electrically isolate the substrate support 110 from the cover ring 154. For this purpose, it may be made from ceramic or other process-compatible dielectric materials. As illustrated in FIG. 1, the process chamber 102 also includes a second RF bias power supply 156, which can be connected to the cover ring 154 through a conductive rod 158 to induce a positive DC bias or provide a synchronized negative DC bias.

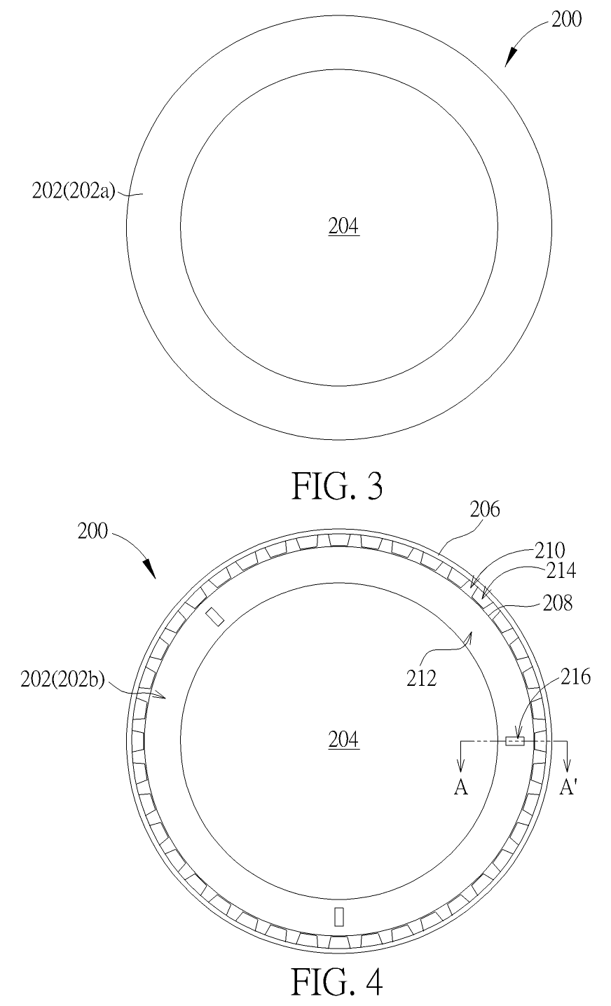

The following embodiments describe the cover ring component 200 of the process kit of the present invention with reference to FIGS. 3 - 5. The cover ring 200 is specifically engineered to interface with the substrate support (including electrostatic chucks) and other components of the process kit during deposition processes, and it may cover portions of these components while the substrate (such as a silicon wafer) is placed on the substrate support. The invention is particularly well-suited for Physical Vapor Deposition (PVD) processes. Embodiments of the present invention, including those depicted in FIGS. 1 and 2, are applicable to a wide range of PVD-based technologies. These include, but are not limited to, Ionized Metal Plasma (IMP), Self-Ionized Plasma (SIP), Enhanced Self-Ionized Plasma (eSIP), and various other PVD process variants. The invention supports deposition of a wide array of materials, encompassing not only pure metals and metal alloys but also metal oxides, nitrides, and silicides, in thin film form. Although the cover ring 200 shown in the figures is illustrated as annular in shape, it is to be understood that the present invention may also adopt other configurations and shapes, such as square , depending on process or tool-specific requirements.

Referring first to FIG. 3, a front plan view of the cover ring 200 is shown. The cover ring 200 may correspond to the cover ring 154 illustrated in FIG. 1, and it is installed on the mechanism/component around the substrate support 110 as part of the overall process kit 144. The cover ring 200 includes an annular body 202, with its front surface 202a depicted in the figure. The annular body 202 defines a central opening 204, which is essentially circular in shape. In actual implementation, when the cover ring 200 is mounted onto the substrate support 110, part of the electrostatic chuck (such as the components 120, 124 shown in FIG. 1) may pass and extend through this opening 204. The cover ring 200 can be made from ceramic material, preferably in monolithic (one-piece) structure, which helps mitigate particle accumulation. During the process, since the process kit 144 consists of multiple individual components (such as cover ring 154, deposition ring 172, shield ring 146, etc., between which small gaps can form), particles may accumulate in the gaps between these components, potentially causing erosion or wear of the rings. Worse yet, particles accumulated in the gaps may fall onto and contaminate the substrate 112. Therefore, by employing a one-piece design for the cover ring 200, such particle accumulation is significantly reduced, minimizing erosion and extending the operational lifespan of the component. Moreover, in the context of the present invention, eliminating gaps between adjacent components enhances gas flow uniformity across the substrate surface during processing, helping to ensure more consistent film quality and improved process reliability.

Next, referring to FIG. 4, a rear plan view of the cover ring 200 is illustrated. FIG. 4 highlights the structural features on the rear surface 202b of the annular body 202, including an outer ring 206 and an inner ring 208, which together define an annular groove 210. In this embodiment, the outer ring 206 is positioned at the outermost edge of the annular body 202 , although this configuration is not strictly limited to such placement. The annular body 202 also has a lip 212 extending radially inward from the inner ring 208 to the opening 204. A significant feature of the cover ring 200 in the present invention is that the bottom surface of the annular groove 210 contains multiple recesses 214, which are circumferentially and evenly spaced along the base of the annular groove 210. Additionally, the lip 212 of the annular body 202 - particularly near the inner ring 208 - also features a number of alignment notches 216, which helps achieve alignment and fixation when the cover ring 200 is installed onto the corresponding structures within the process chamber (such as the deposition ring 172 shown in FIG. 1).

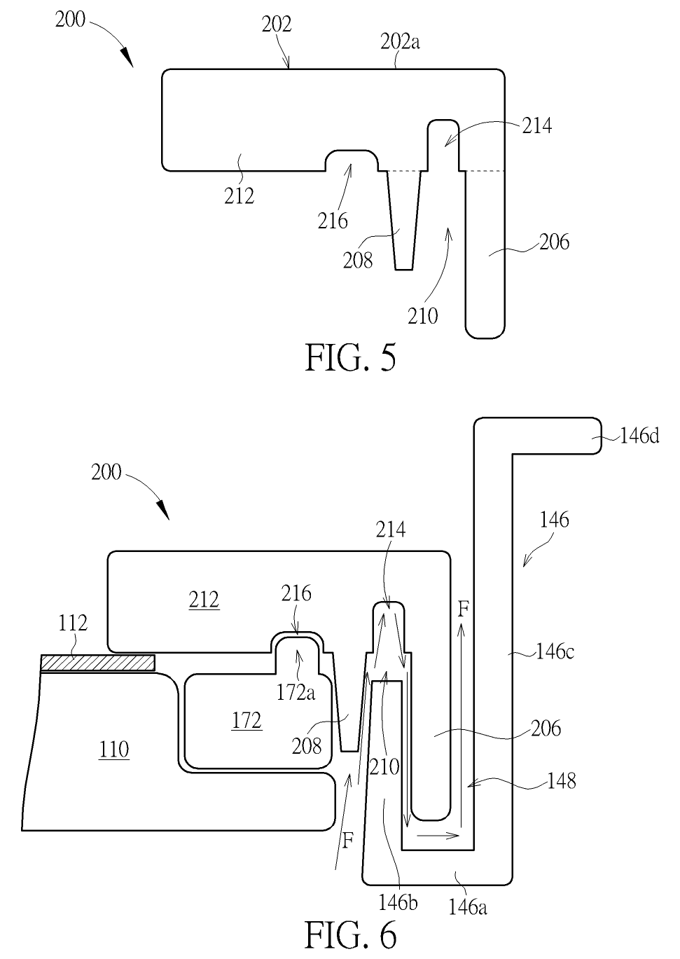

Next, referring to FIG. 5, a cross-sectional view of the cover ring 200 taken along the section line A-A' in FIG. 4 is illustrated. As shown in FIG. 5, the inner ring 208 and the outer ring 206 of the cover ring 200 extend downward from the rear surface 202b of the annular body 202, thereby defining the annular groove 210, wherein the outer ring 206 is preferably positioned at the outermost edge of the annular body 202 and extends downward beyond the inner ring 208. The bottom surface of the annular groove 210 is also formed with recesses 214, which extend into the groove 210 (along the upward direction in the figure). The portion of the annular body 202 that extends radially inward from the inner ring 208 forms the lip 212 of the annular body 202, on which one or more alignment notches 216 are provided. The alignment notch 216 is preferably located close to the inner ring 208, and its depth is preferably less than the depth of the recesses 214.

Now, referring to FIG. 6, which illustrates a schematic cross-sectional view of the process kit of the present invention installed within a substrate process chamber. As shown in FIG. 6, in this embodiment, the process kit of the present invention includes three previously described components: the cover ring 200, deposition ring 172, and the shield ring 146 - although the invention is not limited to these elements alone. In this configuration, the shield ring 146 features a generally vertical outer wall 146c, which connects at its lower end to an inward-extending lower edge portion 146a, and at its upper end to an outward-extending upper edge portion 146d. The shield ring 146 also has an upward-extending end portion 146b projects from the lower edge portion 146a. These three sections—the end portion 146b, the lower edge portion 146a, and the outer wall 146c — collectively define a U-shaped groove 148 that opens upward. Upon assembly of the process kit, the outer ring 206 of the cover ring 200 will be located in the U-shaped groove 148, designed specifically to engage with this groove 148 for precise alignment and structural integration. Meanwhile, the upward-facing end portion 146b of the shield ring 146 is positioned in the annular groove 210 defined by the inner ring 208 and outer ring 206 of the cover ring 200, designed to engage with the annular groove 210, without extending into the recesses 214 on the bottom surface of the groove. Once installed, the interface between the cover ring 200 and shield ring 146 provides sufficient spacing and flow channels to allow process gases or cooling gases to circulate effectively. Furthermore, the upper edge portion 146d of the shield ring 146 is electrically connected to the grounded wall of the process chamber 102 (referenced as element 150 in FIG. 1, though not shown here), serving as part of the RF return path within the overall RF loop of the system.

Referring again to FIG. 6, the deposition ring 172 of the process kit is mounted on the outer periphery of the substrate support 110, serving to shield the edge regions of the substrate support 110 from undesired deposition. In this embodiment, the deposition ring 172 has an upwardly extending protruding part 172a, which is configured to be inserted into the alignment notch 216 of the cover ring 200. This design enables precise alignment and secure engagement between the cover ring 200 and the deposition ring 172. In alternative embodiments, the relative geometry may be reversed—i.e., the cover ring 200 may include the protrusion while the deposition ring 172 provides the corresponding alignment notch—though the invention is not limited to either configuration. During the process, the substrate 112 is electrostatically adhered and held to the substrate support 110, while the surrounding deposition ring 172 preferably spaced apart from the substrate 112 to avoid physical contact. In this embodiment, the lip 212 of the cover ring 200 extends horizontally beyond the deposition ring 172, partially overlapping with the edge of the substrate 112 and the outer portion of the substrate support 110 in the vertical direction, preventing those areas from being affected by deposition.

Referring once more to FIG. 6, during the PVD deposition process, the temperature of the cover ring 200 gradually increases, typically reaching between approximately 300°C and 400°C. Such elevated temperatures can lead to thermal radiation affecting the outer edge of the substrate 112 covered by the cover ring 200 , potentially resulting in process-related defects such as aluminum whiskers (Al whiskers) or other thermal anomalies. To mitigate this issue, a cooling airflow F must be continuously provided during processing to maintain thermal stability. In general, the cooling airflow F is introduced from the bottom of the process chamber (e.g., via the gas source 134 shown in FIG. 1). The airflow travels through interstitial spaces and flow channels between the shield ring 146 and the cover ring 200, flows across the annular groove 210 and the recesses 214 surfaces of the cover ring 200, and continues through the U-shaped groove 148 of the shield ring 146. This configuration facilitates efficient heat transfer, allowing the airflow to carry away excess heat and thereby achieve the desired cooling effect for temperature regulation during deposition.

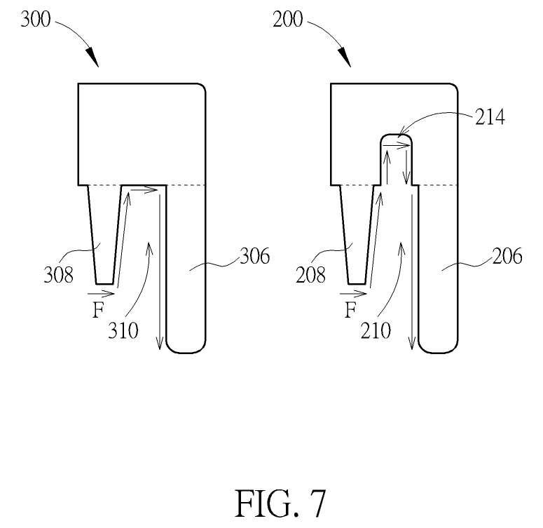

Finally, referring to FIG. 7, which presents a schematic cross-sectional comparison between a conventional cover ring and the cover ring 200 of the present invention during the heat dissipation process. As illustrated, the conventional cover ring 300 includes an outer ring 306 and an inner ring 308, between which only a simple annular groove 310 is formed. This traditional design lacks additional surface-enhancing features, resulting in a limited airflow path and a relatively small heat-exchange surface area. In contrast, the cover ring 200 of the present invention - positioned between its outer ring 206 and inner ring 208 - not only includes a primary annular groove 210, but also features multiple circumferentially distributed recesses 214 on the groove’s bottom surface. When cooling airflow F passes through the groove 210 and over the recesses 214, it contacts a substantially larger surface area of the cover ring 200. This structural enhancement dramatically improves the heat dissipation efficiency of the cover ring. As a result, the thermal radiation emitted from the cover ring 200 toward the outer edge of the substrate is significantly reduced, thereby minimizing the likelihood of thermal-induced defects, such as film non-uniformity or material deformation (e.g., aluminum whiskers). Ultimately, this optimized thermal management contributes to a more uniform and consistent deposition process across the entire substrate surface.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A process kit for a substrate process chamber, comprising:
a cover ring having an annular body and a lip radially extending inward from the annular body, wherein a bottom surface of the annular body comprises an inner ring and an outer ring extending downward to define an annular groove, wherein a bottom surface of the annular groove comprises a plurality of recesses circumferentially and uniformly distributed along the bottom surface of the annular groove; and
a shield ring having a lower edge portion extending inward and an end portion extending upward from the lower edge portion, the end portion being configured to engage with the annular groove of the cover ring.

2. The process kit for a substrate process chamber of claim 1, further comprising a deposition ring configured to be disposed on a substrate support in the substrate process chamber, the deposition ring having a plurality of upwardly extending protruding parts, and a backside of the lip of the cover ring comprises a plurality of alignment notches, each configured to engage with the corresponding protruding part of the deposition ring.

3. The process kit for a substrate process chamber of claim 2, wherein the substrate support is configured to hold a substrate, and the lip of the cover ring extends radially inward to partially overlap an edge of the substrate in a vertical direction.

4. The process kit for a substrate process chamber of claim 2, wherein the substrate support comprises an electrostatic chuck.

5. The process kit for a substrate process chamber of claim 1, further comprising an airflow channel in the annular groove and the recesses between the cover ring and the shield ring.

6. The process kit for a substrate process chamber of claim 1, wherein the shield ring further comprises an outer wall, one end of the outer wall being connected to one end of the lower edge portion, and another end of the outer wall being connected to an upper edge portion extending outward, such that the end portion, the lower edge portion, and the outer wall together define a U-shaped groove having an upward-facing opening, and the outer ring of the cover ring is configured to engage with the U-shaped groove of the shield ring.

7. The process kit for a substrate process chamber of claim 6, further comprising an airflow channel between the outer ring and the U-shaped groove.

8. The process kit for a substrate process chamber of claim 6, wherein the upper edge portion of the shield ring is connected to a grounded wall of the substrate process chamber.

9. A substrate process chamber, comprising:
a substrate support configured to hold a substrate, the substrate support being disposed within an inner processing space of the substrate process chamber and having a deposition ring disposed thereon; and
a process kit disposed at a peripheral edge of the substrate support, the process kit comprising:
a cover ring having an annular body and a lip radially extending inward from the annular body, wherein a bottom surface of the annular body comprises an inner ring and an outer ring extending downward to define an annular groove, and a bottom surface of the annular groove comprises a plurality of recesses circumferentially and uniformly distributed along the bottom surface of the annular groove; and
a shield ring having a lower edge portion extending inward and an end portion extending upward from the lower edge portion, the end portion being configured to engage with the annular groove of the cover ring.

10. The substrate process chamber of claim 9, wherein the deposition ring comprises a plurality of upwardly extending protruding parts, and a backside of the lip of the cover ring comprises a plurality of alignment notches, each configured to engage with a corresponding protruding part of the deposition ring.

11. The substrate process chamber of claim 9, wherein the lip of the cover ring extends radially inward to partially overlap an edge of the substrate in a vertical direction.

12. The substrate process chamber of claim 9, wherein the substrate support comprises an electrostatic chuck.

13. The substrate process chamber of claim 9, further comprising an airflow channel in the annular groove and the recesses between the cover ring and the shield ring.

14. The substrate process chamber of claim 9, wherein the shield ring further comprises an outer wall, one end of the outer wall being connected to one end of the lower edge portion, and another end of the outer wall being connected to an upper edge portion extending outward, such that the end portion, the lower edge portion, and the outer wall together define a U-shaped groove having an upward-facing opening, and the outer ring of the cover ring is configured to engage with the U-shaped groove of the shield ring.

15. The substrate process chamber of claim 14, further comprising an airflow channel between the outer ring and the U-shaped groove.

16. The substrate process chamber of claim 14, wherein the upper edge portion of the shield ring is connected to a grounded wall of the substrate processing chamber.
